(19) United States
(12) Patent Application Publication
(10) Pub. No.: US 2002/0158265 A1
(43) Pub. Date: Oct. 31, 2002

(54) Structure and method for fabricating high contrast reflective mirrors

(75) Inventor: Kurt W. Eisenbeiser, Tempe, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Motorola, Inc.

(21) Appl. No.: 09/842,735

(22) Filed: Apr. 26, 2001

(51) Int. Cl. H01L 29/76; H01L 33/00

(52) U.S. Cl. 257/98; 257/88; 372/45

(57) ABSTRACT

A high contrast reflective mirror includes a plurality of alternating first monocrystalline layers and second monocrystalline layers. The first monocrystalline layers are formed of an oxide material that has a cubic structure and a first index of refraction. The second monocrystalline layers are formed of a semiconductor material that has a second index of refraction. The first index of refraction and the second index of refraction differ by at least about 0.5

### FIELD OF THE INVENTION

This invention relates generally to semiconductor lasers and, more particularly, to a structure and method for fabricating high contrast reflective mirrors for use in vertical-cavity surface-emitting lasers.

### BACKGROUND OF THE INVENTION

Vertical-cavity surface-emitting lasers (VCSELs) have become the subject of increasing interest for use in communications systems and other typical laser applications. This is due, at least in part, to the advantages in the optical beam geometry of these lasers. Surface-emitting lasers comprise large emitter areas that allow for a low divergence angle of laser and, accordingly, improved beam quality. In addition, VCSELs tend to have a short inner cavity length, which results in a very large mode spacing and, hence, single mode operation.

Typically, VCSELs are formed of distributed Bragg reflecting (“DBR”) mirrors that sandwich the active layer and form the vertical cavity. To reduce the overall device dimensions, thereby reducing material costs, it is desirable to fabricate the mirrors so as to produce a short cavity. DBR mirrors typically are formed of a plurality of pairs of layers, each layer having an index of refraction. To produce a short cavity, it is preferable that there be a relatively large difference between the indices of refraction of the layers of the pair. Large-index-step high contrast mirrors require fewer layers than mirrors with lower mirror reflectance. It has been reported that highly reflecting mirrors and short cavity lead to self-stimulated photon emission. See, “Photopumped Room-Temperature Edge- and Vertical-Cavity Operation of AlGaAS-GaAs-InGaAs Quantum-Well Heterostructure Lasers Utilizing Native Oxide Mirrors,” Appl. Phys. Lett. 65(6), p. 740 (Aug. 8, 1994), incorporated herein by reference. In addition, large-index-step high contrast mirrors may obtain very low threshold voltages.

High contrast mirrors have been produced by forming alternating layers of an aluminum-containing material, such as Al_{y}Ga_{1-y}As or InAlAs, and a semiconductor material, such as GaAs or InP, and subsequently oxidizing the aluminum-containing layers. The low index of refraction of the oxidized layers (for oxidized Al_{y}Ga_{1-y}As, ˜1.6) and the high index of refraction of the semiconductor material (for GaAs, ˜3.6) serve to form a suitable large-index-step high contrast mirror. However, oxidation of the aluminum-containing material layers leads to porous and weak interfaces between the oxide layers and the semiconductor material layers. A significant stress may develop which may crack the interface as the aluminum-containing material oxidizes. Such stress also result in the formation of defects in the semiconductor material layers which affect device performance. In addition, oxidation of the aluminum-containing material converts the crystalline structure of the material to an amorphous layer, which causes the volume of the oxidized layer to change, thus creating stresses that result in defects and in the compromise of device reliability.

Accordingly, there is a need for a large-index-step high contrast mirror which exhibits a reduced number of defects. There is also a need for a method for fabricating a high quality large-index-step high contrast mirror which exhibits a reduced number of defects.

In addition, there is a need for a vertical-cavity surface-emitting laser formed of large-index-step high contrast mirrors that exhibit a reduced number of defects.

### BRIEF DESCRIPTION OF THE DRAWINGS

The present invention is illustrated by way of example and not limitation in the accompanying figures, in which like references indicate similar elements, and in which:

FIG. 1 illustrates schematically, in cross-section, a device structure in accordance with an embodiment of the invention;

FIG. 2 illustrates graphically the relationship between maximum attainable film thickness and lattice mismatch between a host crystal and a grown crystalline overlayer; and

FIG. 3 illustrates schematically, in cross-section, a portion of a vertical-cavity surface-emitting layer on a semiconductor substrate according to an embodiment of the present invention.

Skilled artisans will appreciate the elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

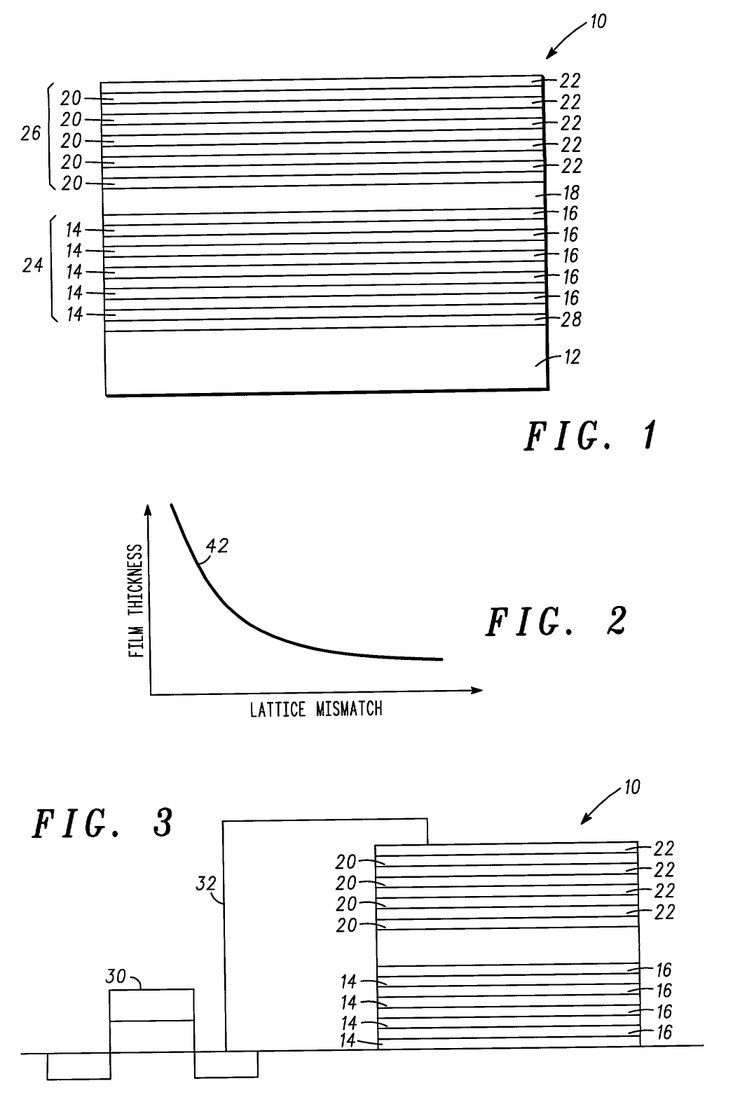

FIG. 1 illustrates schematically, in cross section, a portion of a structure 10, in accordance with an exemplary embodiment of the present invention, which is used to form a vertical-cavity surface-emitting laser. Structure 10 includes a monocrystalline substrate 12, a first distributed Bragg reflector (“DBR”) mirror 24, a monocrystalline active layer 18, and second DBR mirror 26. First DBR mirror 24 is formed of repeating pairs of a first monocrystalline material layer 14 and a second monocrystalline material layer 16. Second DBR mirror 26 is formed of repeating pairs of a third monocrystalline material layer 20 and a fourth monocrystalline material layer 22. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

Substrate 12, in accordance with an embodiment of the invention, is a monocrystalline semiconductor or compound semiconductor material. Substrate 12 can be of, for example, a material from Group IV of the periodic table or a compound material from Groups III and V. Examples of suitable substrate materials include silicon, germanium, mixed silicon and germanium, mixed silicon and carbon, mixed silicon, germanium and carbon, GaAs, InP and the like. Preferably, substrate 12 is formed of high quality monocrystalline silicon wafer as used in the semiconductor industry.

In another embodiment of the invention, substrate 12 may comprise a (001) Group IV material that has been off-cut towards a (110) direction. The growth of materials on a miscut Si (001) substrate is known in the art. For example, U.S. Pat. No. 6,039,803, issued to Fitzgerald et. al on Mar. 21, 2000, which patent is herein incorporated by reference, is directed to growth of silicon-germanium and germanium layers on miscut Si (001) substrates. Substrate 12 may be off-cut in the range of from about 2 degrees to about 6 degrees towards the (110) direction. A miscut Group IV substrate reduces dislocations and results in improved quality of subsequently grown layers.

First monocrystalline material layers 14 of first DBR mirror 24 are preferably formed of an epitaxially-grown monocrystalline oxide material having a cubic crystal structure which is selected for its crystalline compatibility with the underlying substrate and with the overlying second monocrystalline material layers 16. Materials that are suitable for first monocrystalline material layers 14 include cubic-crystal-structure metal oxides formed of alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Other suitable materials may include epitaxial cubic metal oxides such as magnesium oxide, strontium oxide and aluminum oxide.

The material for second monocrystalline material layers 16 may be selected for its crystalline compatibility with first monocrystalline material layers 14 and active layer 18. For example, second monocrystalline material layers 16 may be formed of material selected from any of the Group IIIA and VA elements (III-V semiconductor compounds), mixed III-V compounds, Group II (A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe) and the like.

It is well-known that the reflectivity of the DBR mirror is generally a function of the difference in the refractive indices between the first monocrystalline material layer and the second monocrystalline material layer and the number of layer pairs in the structure. The greater the difference in the refractive indices, the fewer number of pairs are required to obtain a given reflectivity. Thus, it is preferable that the indices of refraction of the first monocrystalline material layer and the second monocrystalline material layer differ by at least about 0.5 and more preferably at least about 1. In accordance with one exemplary embodiment of the invention, first monocrystalline material layers 14 may be formed of barium strontium titanate (Ba,Sr)TiO₃, having an index of refraction of approximately 2.2, and second monocrystalline material layers 16 may be formed of GaAs, having an index of refraction of approximately 3.6. Because of the large difference in indices of refraction of the two layers, DBR mirror 24 may comprise as few as five to twenty pairs of layers 14 and 16, and preferably comprise five to ten pairs. In this manner, a high contrast mirror with a short cavity is obtained.

The crystalline structure of first material layer 14 is characterized by a lattice constant and a lattice orientation. In a similar manner, second material layer 16 is characterized by lattice constant and a lattice orientation. As used herein, lattice constant refers to the distance between atoms of a cell measured in the plane of the surface. To fabricate a relatively defect-free mirror, it is preferable that first monocrystalline material layer 14 and second material layer 16 have lattice constants that are closely matched, or, alternatively, upon rotation of one crystal orientation with respect to the other crystal orientation, have achieved a substantial match in lattice constants. In this context, the terms “substantially matched” and “substantially equal” mean that there is sufficient similarity between the lattice constants to permit the growth of a high quality crystalline layer on the underlying layer.

FIG. 2 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

Referring again to FIG. 1, in accordance with one embodiment of the invention, structure 10 may also include an amorphous intermediate layer 28 positioned between substrate 12 and first DBR mirror 24. The amorphous intermediate layer 28 is grown on substrate 12 at the interface between substrate 12 and the first layer of the first DBR mirror 24 by oxidation of substrate 12 during growth of the first layer of DBR mirror 24. The amorphous intermediate layer may help to relieve the strain in the first layer of the DBR mirror 24 and by doing so, may aid in the growth of a high crystalline quality first DBR mirror 24. If structure 10 does not include an amorphous intermediate layer 28, it is preferable that the material forming substrate 12 and the material forming first monocrystalline material layers 14 be substantially lattice matched to ensure the growth of a high quality DBR mirror.

Active layer 18 may be formed of a material selected based on a desired output wavelength of the laser structure. Examples of suitable materials include gallium arsenide (GaAs), gallium aluminum arsenide (GaAlAs), gallium indium arsenide (GaInAs), gallium indium arsenide phosphide (GaInAsP), and the like.

Second DBR mirror 26 includes repeating pairs of third monocrystalline material layer 20 and fourth monocrystalline material layer 22. As with first DBR 22, it is preferable that layers 20 and layers 22 have sufficiently different indices of refraction that a high reflectivity mirror having a short cavity is obtained. Preferably the indices of refraction of the layers differ by at least about 0.5 and more preferably differ by at least about 1. It is also preferable that layers 20 and 22 have lattice constants that are substantially matched. Accordingly, materials suitable for third monocrystalline material layers 20 include those materials described above as suitable for first monocrystalline material layers 14. Similarly, materials suitable for fourth monocrystalline material layers 22 include those materials described above as suitable for second monocrystalline material layers 16. Third monocrystalline material layers 20 may be formed of the same material as that forming first monocrystalline material layers 14 or may be formed of a different cubic oxide material. Fourth monocrystalline material layers 22 may be formed of the same material as that forming second monocrystalline material layers 16 or may be formed of a different semiconductor material.

In accordance with another embodiment of the invention, structure 10 may also include an amorphous intermediate layer (not shown) positioned between active layer 18 and second DBR mirror 26. The amorphous intermediate layer is grown on active layer 18 at the interface of active layer 18 and the first layer of second DBR mirror 26 by oxidation of the active layer during growth of the first layer of second DBR mirror 26. Again, the amorphous intermediate layer may help to relieve the strain in the first layer of the second DBR mirror 26 and, by doing so, may aid in the growth of a high crystalline quality second DBR mirror 24. If structure 10 does not include an amorphous intermediate layer between the active layer 18 and the first layer of the DBR mirror 26, it is preferable that the material forming active layer 18 and the material forming third monocrystalline material layers 20 be substantially lattice matched to ensure the growth of a high quality DBR mirror.

Referring to FIG. 3, structure 10 may be coupled to a CMOS device 30 via any suitable electrical connection 32 to form an optoelectronic integrated circuit. CMOS device 30 may comprise at least one device such as a MOSFET which is formed by conventional semiconductor processing as is well known and widely practiced in the semiconductor industry.

The following non-limiting, illustrative examples illustrate various combinations of materials useful in structure 10 in accordance with various alternative embodiments of the invention. These examples are merely illustrative, and it is not intended that the invention be limited to these illustrative examples.

### EXAMPLE 1

In accordance with one embodiment of the invention, monocrystalline substrate 12 is a silicon substrate oriented in the (100) direction. The silicon substrate can be, for example, a silicon substrate as is commonly used in making complementary metal oxide semiconductor (CMOS) integrated circuits. In accordance with this embodiment of the invention, first monocrystalline material layers 14 and third monocrystalline material layers 20 are monocrystalline material layers of SrₓBa₁₋ₓTiO₃, where x ranges from 0 to 1. The value of x is selected to obtain one or more lattice constants closely matched to corresponding lattice constants of the subsequently formed second monocrystalline material layers 16 and fourth monocrystalline material layers 22. First monocrystalline material layers 14 and third monocrystalline material layers 20 typically have a thickness of about one-quarter of the wavelength of the desired light to be emitted from the formed laser, and preferably have a thickness of from about 500 angstroms to about 5000 angstroms. In accordance with this embodiment, an amorphous intermediate layer positioned between the silicon substrate and the first oxide layer of first DBR mirror 24 is formed of a silicon oxide that may have a thickness of about 0.5 to 5 nm, and preferably a thickness of about 1 to 2 nm.

Second monocrystalline material layers 16 and fourth monocrystalline material layers 22 are monocrystalline material layers of AlGaAs. Second monocrystalline material layers 16 and fourth monocrystalline material layers 22 also typically have a thickness of about one-quarter of the wavelength of the desired emitted light, and preferably have a thickness of from about 500 angstroms to about 5000 angstroms. In accordance with this embodiment of the invention, active layer 18 is a monocrystalline material layer of GaAs having a thickness of about 1000 angstroms to about 3 μm and preferably having a thickness of about 2500 angstroms.

### EXAMPLE 2

In accordance with another embodiment of the invention, monocrystalline substrate 12 is an InP substrate. First monocrystalline material layers 14 of first DBR mirror 24 are formed of SrₓBa₁₋ₓZrO₃, where x ranges from 0 to 1 and is selected to obtain one or more lattice constants closely matched to corresponding lattice constants of the subsequently formed second monocrystalline layers 16. First monocrystalline material layers 14 may have a thickness in the range of from about 500 angstroms to about 5000 angstroms. Second monocrystalline material layers 16 may be formed of InP with a thickness of from about 500 angstroms to about 5000 angstroms. In accordance with this embodiment of the invention, active layer 18 is a monocrystalline material layer of GaInAsP having a thickness in the range of about 2000 angstroms to 5 μm and preferably having a thickness of about 4500 angstroms.

Third monocrystalline material layers 20 of second DBR mirror 26 may be formed of the same material as used to form first monocrystalline material layers 14 or may be formed of another suitable material. In this embodiment, third monocrystalline material layers 20 may be formed of Sr_{z}Ba_{1-z}SnO₃, where z ranges from 0 to 1 and z is selected to obtain one or more lattice constants closely matched to corresponding lattice constants of the subsequently formed fourth monocrystalline layers 22. Third monocrystalline material layers 20 may have a thickness of from about 500 angstroms to about 5000 angstroms. Fourth monocrystalline material layers 22 may be formed of InP with a thickness of from about 500 angstroms to about 5000 angstroms.

Still referring to FIG. 1, first and third layers 14 and 20 and second and fourth material layers 16 and 22 are layers of epitaxially grown monocrystalline materials that are characterized by crystal lattice constants and crystal orientations. In accordance with one embodiment of the invention, the lattice constants of first and third layers 14 and 20 differ from the lattice constants of third and fourth layers 16 and 22, respectively. To achieve high quality DBR mirrors, the layers of the mirrors should be of high crystalline quality. To achieve high crystalline quality in the layers of the mirrors, substantial matching between the crystal lattice constants of the layers is desired. With properly selected materials this substantial matching of lattice constants is achieved as a result of rotation of the crystal orientation of the grown crystal with respect to the orientation of the underlying host crystal. For example, if layers 16 are formed of gallium arsenide or gallium aluminum arsenide and layers 14 are formed of SrₓBa₁₋ₓTiO₃, substantial matching of crystal lattice constants of the two materials is achieved, wherein the crystal orientation of the grown layer is rotated by 45 degrees with respect to the orientation of the host monocrystalline oxide. Similarly, if layers 14 are formed of strontium or barium zirconate and layers 16 are formed of indium phosphide or gallium indium phosphide, substantial matching of crystal lattice constants can be achieved by rotating the orientation of the grown crystal layer by 45 degrees with respect to the underlying crystal layer.

The following example illustrates a process, in accordance with one embodiment of the invention, for fabricating a semiconductor structure such as the structure depicted in FIG. 1. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 2° to 6° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface exhibits an ordered 2×1 structure. If an ordered 2×1 structure has not been achieved at this stage of the process, the structure may be exposed to additional strontium until an ordered 2×1 structure is obtained. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of barium strontium titanate is grown on the template layer by molecular beam epitaxy. The MBE process is initiated by opening shutters in the MBE apparatus to expose barium, strontium, titanium and oxygen sources. The partial pressure of oxygen is initially set at a minimum value to grow barium strontium titanate at a growth rate of about 0.3-0.5 nm per minute. After initiating growth of the barium strontium titanate, the partial pressure of oxygen is increased above the initial minimum value. The overpressure of oxygen causes the growth of an amorphous silicon oxide layer at the interface between the underlying substrate and the growing barium strontium titanate layer. The growth of the silicon oxide layer results from the diffusion of oxygen through the growing barium strontium titanate layer to the interface where the oxygen reacts with silicon at the surface of the underlying substrate. The barium strontium titanate grows as an ordered monocrystal with the crystalline orientation rotated by 45° with respect to the ordered 2×1 crystalline structure of the underlying substrate. Strain that otherwise might exist in the barium strontium titanate layer because of the small mismatch in lattice constant between the silicon substrate and the growing crystal is relieved in the amorphous silicon oxide intermediate layer.

After the barium strontium titanate layer has been grown to the desired thickness, the monocrystalline barium strontium titanate is capped by a template layer that is conducive to the subsequent growth of an epitaxial layer of a desired monocrystalline material. For example, for the subsequent growth of a monocrystalline compound semiconductor material layer of aluminum gallium arsenide, the MBE growth of the barium strontium titanate monocrystalline layer can be capped by terminating the growth with 1-2 monolayers of titanium, 1-2 monolayers of titanium-oxygen, with 1-2 monolayers of strontium-oxygen, with 1-2 monolayers of barium-oxygen or with 1-2 layers of aluminum. Following the formation of this capping layer, arsenic is deposited to form a Ti—As bond, a Ti—O—As bond, a Br—O—As bond, an Al—As bond, an Al—O—As bond or a Sr—O—As bond. Any of these form an appropriate template for deposition and formation of an aluminum gallium arsenide monocrystalline layer. Following the formation of the template, aluminum and gallium are subsequently introduced to the reaction with the arsenic and aluminum gallium arsenide forms. Alternatively, gallium and aluminum can be deposited on the capping layer to form a Sr—O—Al bond or a Sr—O—Ga bond, and arsenic is subsequently introduced with the aluminum and gallium to form the AlGaAs.

The processes described above for growing the barium strontium titanate layer and AlGaAs layer are suitably repeated to form a first DBR mirror having multiple alternating layers of barium strontium titanate and AlGaAs. Preferably, the processes are repeated 5 to 10 times so that the first DBR mirror has 5 to 10 pairs of layers, each pair comprising a layer of AlGaAs overlying a layer of barium strontium titanate.

After formation of the first DBR mirror, an active layer is epitaxially deposited overlying the first DBR mirror. In this example, gallium continues to be introduced to the reaction with arsenic to form an active layer of GaAs.

After formation of the active layer, a second DBR mirror is deposited overlying the active layer. In accordance with this embodiment of the invention, the second DBR mirror may be formed from the same materials and using the same processes as the first DBR mirror. After formation of the second DBR, structure 10 may be suitably integrated into a semiconductor device to form a VCSEL circuit.

The process described above illustrates a process for forming a semiconductor structure including a silicon substrate, a first DBR mirror, an active layer and a second DBR mirror by the process of molecular beam epitaxy (MBE). The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline oxide layers having cubic crystalline structures formed of alkaline earth metal titanates, zirconates, hafnates, tantalates, vanadates, ruthenates, and niobates, perovskite oxides such as alkaline earth metal tin-based perovskites, lanthanum aluminate, lanthanum scandium oxide, and gadolinium oxide can also be grown. Further, by a similar process such as MBE, other monocrystalline semiconductor layers comprising other III-V and II-VI monocrystalline compound semiconductors can be deposited over the oxide layers of the DBR mirrors.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, solution to occur or become more pronounced are not to be constructed as critical, required, or essential features or elements of any or all of the claims. As used, herein, the terms “comprises,” “comprising” or any other variation thereof, are intended to cover a non-exclusive inclusion, such that a process, method, article, or apparatus that comprises a list of elements does not include only those elements but may include other elements not expressly listed or inherent to such process, method, article, or apparatus.

I claim:

1. A high contrast reflective mirror comprising:
a plurality of alternating first monocrystalline layers and second monocrystalline layers,
wherein said first monocrystalline layers comprise an oxide material having a cubic structure and a first index of refraction;
wherein said second monocrystalline layers comprise a semiconductor material having a second index of refraction, and
wherein said first index of refraction and said second index of refraction differ by at least about 0.5.

2. The high contrast reflective mirror of claim 1, wherein said first index of refraction and said second index of refraction differ by at least about 1.0.

3. The high contrast reflective mirror of claim 1, wherein said first monocrystalline layers comprise an oxide material selected from the group consisting of alkaline earth metal titanates, alkaline earth metal zirconates, alkaline earth metal hafnates, alkaline earth metal tantalates, alkaline earth metal ruthenates, alkaline earth metal niobates and metal oxides.

4. The high contrast reflective mirror of claim 3, wherein said first monocrystalline layers comprise SrₓB₁₋ₓTiO₃, where x ranges from 0 to 1.

5. The high contrast reflective mirror of claim 1, wherein said second monocrystalline layers comprise one of a semiconductor or compound semiconductor material.

6. The high contrast reflective mirror of claim 5, wherein said second monocrystalline layers comprise a compound semiconductor material selected from the group consisting of GaAs, GaAlAs, InP, GaInAs, GaInP, CdS, CdHgTe, PbSe, PbTe, PbSSe, ZnSe and ZnSeS.

7. The high contrast reflective mirror of claim 1, wherein said first monocrystalline layers are characterized by a first lattice constant and said second monocrystalline layers are characterized by a second lattice constant which is substantially lattice matched to said first lattice constant.

8. A vertical-cavity surface-emitting laser comprising:
a monocrystalline substrate;
a first DBR mirror epitaxially grown overlying said substrate, wherein said first DBR mirror comprises:
a plurality of alternating first monocrystalline layers and second monocrystalline layers,
wherein said first monocrystalline layers comprise an oxide material having a cubic structure and a first index of refraction;
wherein said second monocrystalline layers comprise a semiconductor material having a second index of refraction, and
wherein said first index of refraction and said second index of refraction differ by at least about 0.5;
an active layer epitaxially grown overlying said first DBR mirror; and
a second DBR mirror epitaxially grown overlying said active layer, wherein said second DBR mirror comprises:
a plurality of alternating third monocrystalline layers and fourth monocrystalline layers,
wherein said third monocrystalline layers comprise an oxide material having a cubic structure and a third index of refraction;
wherein said fourth monocrystalline layers comprise a semiconductor material having a fourth index of refraction, and
wherein said third index of refraction and said fourth index of refraction differ by at least about 0.5.

9. The vertical-cavity surface-emitting laser of claim 8, wherein the substrate comprises silicon.

10. The vertical-cavity surface-emitting laser of claim 8, further comprising an amorphous oxide layer overlying said substrate and underlying said first DBR mirror.

11. The vertical-cavity surface-emitting laser of claim 8, further comprising an amorphous oxide layer overlying said active layer and underlying said second DBR mirror.

12. The vertical-cavity surface-emitting laser of claim 8, wherein said first index of refraction and said second index of refraction differ by at least about 1.0.

13. The vertical-cavity surface-emitting laser of claim 8, wherein said third index of refraction and said fourth index of refraction differ by at least about 1.0.

14. The vertical-cavity surface-emitting laser of claim 8, wherein said first monocrystalline layers comprise an oxide selected from the group consisting of alkaline earth metal titanates, alkaline earth metal zirconates, alkaline earth metal hafnates, alkaline earth metal tantalates, alkaline earth metal ruthenates, alkaline earth metal niobates and metal oxides.

15. The vertical-cavity surface-emitting laser of claim 8, wherein said third monocrystalline layers comprise an oxide selected from the group consisting of alkaline earth metal titanates, alkaline earth metal zirconates, alkaline earth metal hafnates, alkaline earth metal tantalates, alkaline earth metal ruthenates, alkaline earth metal niobates and metal oxides.

16. The vertical-cavity surface-emitting laser of claim 14, wherein said first monocrystalline layers comprise SrₓB₁₋ₓTiO₃, where x ranges from 0 to 1.

17. The vertical-cavity surface-emitting laser of claim 15, wherein said third monocrystalline layers comprise SrₓB₁₋ₓTiO₃, where x ranges from 0 to 1.

18. The vertical-cavity surface-emitting laser of claim 8, wherein said second monocrystalline layers comprise one of a semiconductor or compound semiconductor material.

19. The vertical-cavity surface-emitting laser of claim 8, wherein said fourth monocrystalline layers comprise one of a semiconductor or compound semiconductor material.

20. The vertical-cavity surface-emitting laser of claim 18, wherein said second monocrystalline layers comprise a compound semiconductor material selected from the group consisting of GaAs, GaAlAs, InP, GaInAs, GaInP, CdS, CdHgTe, PbSe, PbTe, PbSSe, ZnSe and ZnSeS.

21. The vertical-cavity surface-emitting laser of claim 19, wherein said fourth monocrystalline layers comprise a compound semiconductor material selected from the group consisting of GaAs, GaAlAs, InP, GaInAs, GaInP, CdS, CdHgTe, PbSe, PbTe, PbSSe, ZnSe and ZnSeS.

22. The vertical-cavity surface-emitting laser of claim 8, wherein said active layer comprises material selected from the group comprising GaAs, GaAlAs, GaInAs, and GaInAsP.

23. The vertical-cavity surface-emitting laser of claim 8, wherein said first monocrystalline material layers are characterized by a first lattice constant and said second monocrystalline layers are characterized by a second lattice constant which is substantially lattice matched to said first lattice constant.

24. The vertical-cavity surface-emitting laser of claim 8, wherein said third monocrystalline layers are characterized by a third lattice constant and said fourth monocrystalline layers are characterized by a fourth lattice constant which is substantially lattice matched to said third lattice constant.

25. A vertical-cavity surface-emitting laser circuit comprising:
a monocrystalline substrate;
a portion of an MOS circuit formed in said substrate;
a portion of a vertical-cavity surface-emitting laser overlying said substrate, wherein said portion of said vertical-cavity surface-emitting laser comprises:
a first DBR mirror epitaxially grown overlying said substrate, wherein said first DBR mirror comprises:
a plurality of alternating first monocrystalline layers and second monocrystalline layers,
wherein said first monocrystalline layers comprise an oxide material having a cubic structure and a first index of refraction;
wherein said second monocrystalline layers comprise a semiconductor material having a second index of refraction, and
wherein said first index of refraction and said second index of refraction differ by at least about 0.5;
an active layer epitaxially grown overlying said first DBR mirror;
a second DBR mirror epitaxially grown overlying said active layer, wherein said second DBR mirror comprises:
a plurality of alternating third monocrystalline layers and fourth monocrystalline layers;
wherein said third monocrystalline layers comprise an oxide material having a cubic structure and a third index of refraction;
wherein said fourth monocrystalline layers comprise a semiconductor material having a fourth index of refraction, and
wherein said third index of refraction and said fourth index of refraction differ by at least about 0.5; and
an electrical connection electrically coupling said portion of an MOS circuit and said portion of a vertical-cavity surface-emitting laser.

26. The vertical-cavity surface-emitting laser circuit of claim 25, wherein the substrate comprises silicon.

27. The vertical-cavity surface-emitting laser circuit of claim 25, further comprising an amorphous oxide layer overlying said substrate and underlying said first DBR mirror.

28. The vertical-cavity surface-emitting laser circuit of claim 25, further comprising an amorphous oxide layer overlying said active layer and underlying said second DBR mirror.

29. The vertical-cavity surface-emitting laser circuit of claim 25, wherein said first index of refraction and said second index of refraction differ by at least about 1.0.

30. The vertical-cavity surface-emitting laser circuit of claim 25, wherein said third index of refraction and said fourth index of refraction differ by at least about 1.0.

31. The vertical-cavity surface-emitting laser circuit of claim 25, wherein said first monocrystalline layers comprise an oxide selected from the group consisting of alkaline earth metal titanates, alkaline earth metal zirconates, alkaline earth metal hafnates, alkaline earth metal tantalates, alkaline earth metal ruthenates, alkaline earth metal niobates and metal oxides.

32. The vertical-cavity surface-emitting laser circuit of claim 25, wherein said third monocrystalline layers comprise an oxide selected from the group consisting of alkaline earth metal titanates, alkaline earth metal zirconates, alkaline earth metal hafnates, alkaline earth metal tantalates, alkaline earth metal ruthenates, alkaline earth metal niobates and metal oxides.

33. The vertical-cavity surface-emitting laser circuit of claim 31, wherein said first monocrystalline layers comprise SrₓB₁₋ₓTiO₃, where x ranges from 0 to 1.

34. The vertical-cavity surface-emitting laser circuit of claim 32, wherein said third monocrystalline layers comprise SrₓB₁₋ₓTiO₃, where x ranges from 0 to 1.

35. The vertical-cavity surface-emitting laser circuit of claim 25, wherein said second monocrystalline layers comprise one of a semiconductor or compound semiconductor material.

36. The vertical-cavity surface-emitting laser circuit of claim 25, wherein said fourth monocrystalline layers comprise one of a semiconductor or compound semiconductor material.

37. The vertical-cavity surface-emitting laser circuit of claim 35, wherein said second monocrystalline layers comprise a compound semiconductor material selected from the group consisting of GaAs, GaAlAs, InP, GaInAs, GaInP, CdS, CdHgTe, PbSe, PbTe, PbSSe, ZnSe and ZnSeS.

38. The vertical-cavity surface-emitting laser circuit of claim 36, wherein said fourth monocrystalline layers comprise a compound semiconductor material selected from the group consisting of GaAs, GaAlAs, InP, GaInAs, GaInP, CdS, CdHgTe, PbSe, PbTe, PbSSe, ZnSe and ZnSeS.

39. The vertical-cavity surface-emitting laser circuit of claim 25, wherein said active layer comprises material selected from the group comprising GaAs, GaAlAs, GaInAs, and GaInAsP.

40. The vertical-cavity surface-emitting laser circuit of claim 25, wherein said first monocrystalline material layers are characterized by a first lattice constant and said second monocrystalline layers are characterized by a second lattice constant which is substantially lattice matched to said first lattice constant.

41. The vertical-cavity surface-emitting laser circuit of claim 25, wherein said third monocrystalline layers are characterized by a third lattice constant and said fourth monocrystalline layers are characterized by a fourth lattice constant which is substantially lattice matched to said third lattice constant.

42. A process for fabricating a high contrast reflective mirror comprising:
providing a monocrystalline substrate;
epitaxially growing alternating first monocrystalline layers and second monocrystalline layers,
wherein said first monocrystalline layers comprise an oxide material having a cubic structure and a first index of refraction,
wherein said second monocrystalline layers comprise a semiconductor material having a second index of refraction, and
wherein said first index of refraction and said second index of refraction differ by at least 0.5.

43. The process of claim 42, wherein said growing comprises growing alternating first monocrystalline layers and second monocrystalline layers wherein said first index of refraction and said second index of refraction differ by at least about 1.0.

44. The process of claim 42, wherein said growing comprises growing first monocrystalline layers formed of an oxide material selected from the group consisting of alkaline earth metal titanates, alkaline earth metal zirconates, alkaline earth metal hafnates, alkaline earth metal tantalates, alkaline earth metal ruthenates, alkaline earth metal niobates and metal oxides.

45. The process of claim 42, wherein said growing comprises growing first monocrystalline layers formed of SrₓB₁₋ₓTiO₃, where x ranges from 0 to 1.

46. The process of claim 42, wherein said growing comprises growing second monocrystalline layers formed of one of a semiconductor or a compound semiconductor material.

47. The process of claim 46, wherein said growing comprises growing second monocrystalline layers formed of a compound semiconductor material selected from the group consisting of GaAs, GaAlAs, InP, GaInAs, GaInP, CdS, CdHgTe, PbSe, PbTe, PbSSe, ZnSe and ZnSeS.

48. The process of claim 42, wherein said growing comprises growing alternating first monocrystalline layers having a first lattice constant and second monocrystalline layers having a second lattice constant, and wherein said second lattice constant is substantially lattice matched to said first lattice constant.
